(19) United States
(12) Patent Application Publication
(10) Pub. No.: US 2014/0148011 A1
(43) Pub. Date: May 29, 2014

(54) METHOD OF FORMING SEMICONDUCTOR FINS

(71) Applicant: GLOBALFOUNDRIES INC., (US)

(72) Inventors: Dae-han Choi, Albany, NY (US); Dae Geun Yang, Watervliet, NY (US); Chang Ho Maeng, Clifton Park, NY (US)

(73) Assignee: GLOBALFOUNDRIES INC., Grand Cayman (KY)

(21) Appl. No.: 13/688,258

(22) Filed: Nov. 29, 2012

(51) Int. Cl. H01L 21/3065

(52) U.S. Cl. CPC H01L 21/3065
USPC 438/696

(57) ABSTRACT

An improved method of forming semiconductor fins is disclosed. Cavities are formed by etching a semiconductor substrate to a first depth. A surface treatment layer such as a nitride layer is then deposited or formed on the interior surface of the cavities. The etch then continues deeper, while the surface treatment layer protects the upper portion of the cavities.

### FIELD OF THE INVENTION

The present invention relates generally to semiconductor fabrication and, more particularly, to the forming of semiconductor fins.

### BACKGROUND

As the trend towards miniaturization of electronic products continues, there is a need to increase circuit density. Fin field effect transistors (finFETs) are becoming more prevalent in designs with increased circuit density. It is therefore desirable to have improved methods of forming semiconductor fins.

### SUMMARY OF THE INVENTION

In general, embodiments of the invention provide an improved method of forming semiconductor fins. Cavities are formed by etching a semiconductor substrate to a first depth. A surface treatment layer such as a nitride layer is then formed on the interior surface of the cavities. This may be accomplished by subjecting the cavities to nitrogen-rich plasma. The etching then continues deeper, while the surface treatment layer protects the upper portion of the cavities. The surface treatment layer is preferably hydrophobic, and prevents the fins from sticking to each other during post-etch wet clean processing. Hence, embodiments of the present invention serve to reduce device variability and improve yield for fin devices such as finFETs.

A first aspect of the present invention includes a method of forming fins in a semiconductor substrate, comprising: forming a cavity in the semiconductor substrate, the cavity having a first depth; forming a surface treatment on an interior surface of the cavity; and extending the cavity to a second depth.

A second aspect of the present invention includes a method of forming fins in a semiconductor substrate, comprising: forming a plurality of cavities in the semiconductor substrate, the plurality of cavities each having a first depth; forming a surface treatment on an interior surface of each cavity of the plurality of cavities; extending each cavity of the plurality of cavities to a second depth; and performing a wet clean process on the semiconductor substrate.

A third aspect of the present invention includes a method of forming fins in a semiconductor substrate, comprising: forming a plurality of cavities in the semiconductor substrate, the plurality of cavities each having a first depth; forming a first surface treatment on an interior surface of each cavity of the plurality of cavities, extending each cavity of the plurality of cavities to a second depth; forming a second surface treatment on the interior surface of each cavity of the plurality of cavities; and extending each cavity of the plurality of cavities to a third depth.

### BRIEF DESCRIPTION OF THE DRAWINGS

These and other features of this invention will be more readily understood from the following detailed description of the various aspects of the invention taken in conjunction with the accompanying drawings in which:

FIG. 1 shows a semiconductor structure at a starting point for illustrative embodiments of the present invention.

FIG. 2 shows a semiconductor structure according to illustrative embodiments after a subsequent process step of performing a first etch.

FIG. 3 shows a semiconductor structure according to illustrative embodiments after a subsequent process step of forming a surface treatment layer on the interior surface of the cavities;

FIG. 4 shows a semiconductor structure according to illustrative embodiments after a subsequent process step of performing a second etch.

FIG. 5 shows a semiconductor structure according to illustrative embodiments after a step of depositing an additional surface treatment layer.

FIG. 6 shows a semiconductor structure according to illustrative embodiments after a subsequent step of performing a third etch.

FIG. 7 is a flowchart indicating process steps for illustrative embodiments of the present invention.

The drawings are not necessarily to scale. The drawings are merely representations, not intended to portray specific parameters of the invention. The drawings are intended to depict only typical embodiments of the invention, and therefore should not be considered as limiting in scope. In the drawings, like numbering represents like elements.

### DETAILED DESCRIPTION

Exemplary embodiments will now be described more fully herein with reference to the accompanying drawings, in which exemplary embodiments are shown. Exemplary embodiments of the invention provide an improved method of forming semiconductor fins. Cavities are formed by etching a semiconductor substrate to a first depth. A surface treatment layer such as a nitride layer is then deposited or formed on the interior surface of the cavities. The etching then continues deeper, while the surface treatment layer protects the upper portion of the cavities. The surface treatment layer is preferably hydrophobic, and prevents the fins from sticking to each other during post-etch wet clean processing. Hence, embodiments of the present invention serve to reduce device variability and improve yield for fin devices such as finFETs.

It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure (e.g., a first layer), is present on a second element, such as a second structure (e.g. a second layer), wherein intervening elements, such as an interface structure (e.g. interface layer), may be present between the first element and the second element.

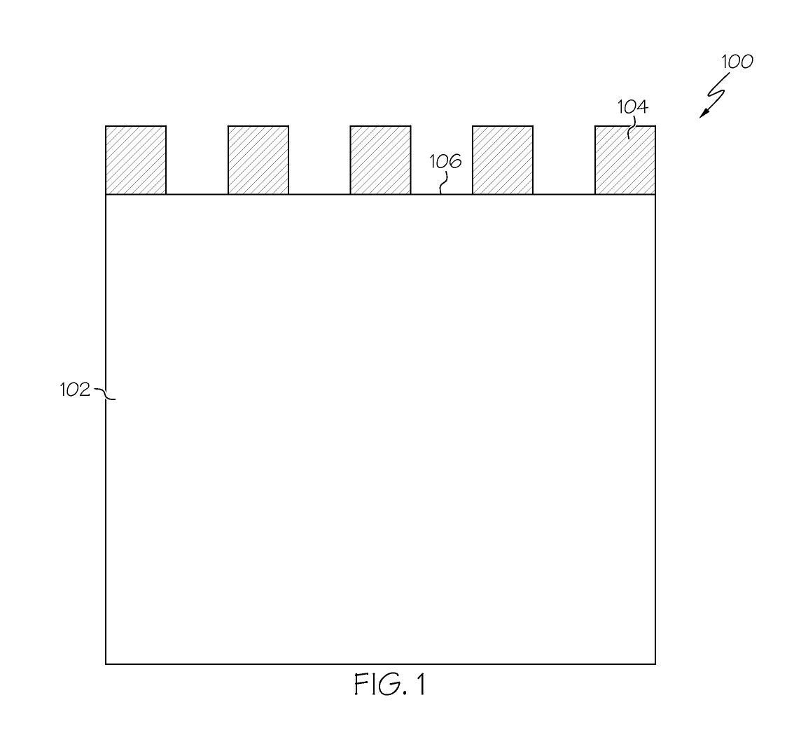

FIG. 1 shows a semiconductor structure 100 at a starting point for embodiments of the present invention. Semiconductor structure 100 comprises a substrate 102, which may comprise silicon. The silicon may be “bulk” silicon which is part of a wafer, or may be a thin silicon-on-insulator (SOI) layer that is disposed over an insulator layer. In addition to silicon, substrate 102 may comprise germanium, silicon germanium, or other suitable semiconductor material. Pad nitride regions 104 are formed on the top of substrate 102. Pad nitride regions 104 may be formed by performing a blanket nitride deposition, followed by patterning using industry-standard lithographic and removal methods. The top surface 106 of substrate 102 is exposed in the areas between the pad nitride regions 104.

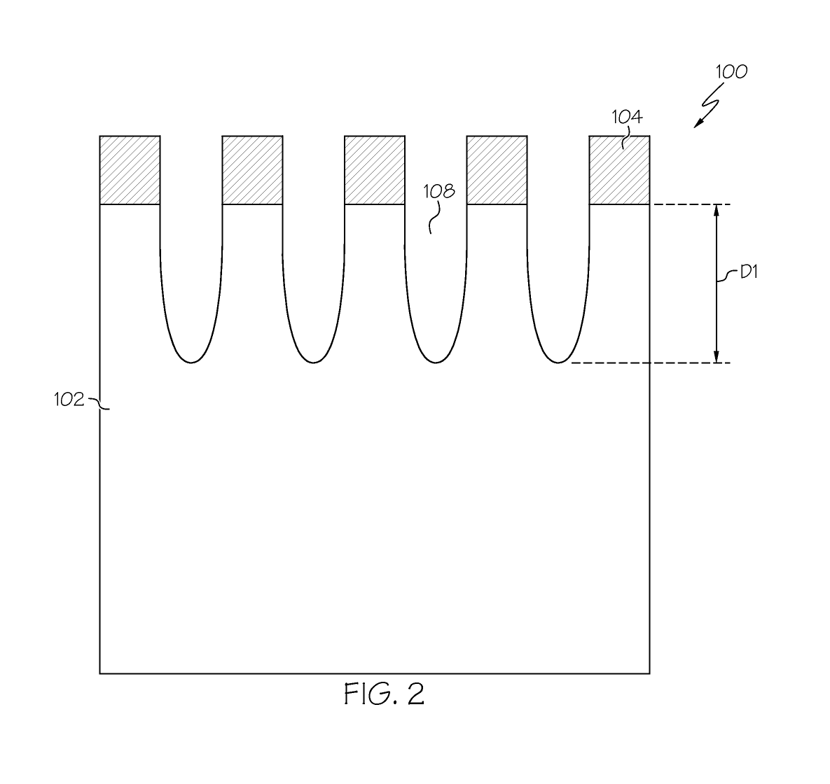

FIG. 2 shows semiconductor structure 100 after a subsequent process step of performing a first etch. The etch may be an anisotropic etch, and may be performed using a reactive ion etch (RIE) process. The first etch has a depth D1, which in some embodiments, may be in the range of about 20 nanometers to about 40 nanometers. In other embodiments, the first etch depth D1 may be in the range of about 30 nanometers to about 50 nanometers. As a result of the first etch, cavities 108 are formed in the substrate 102.

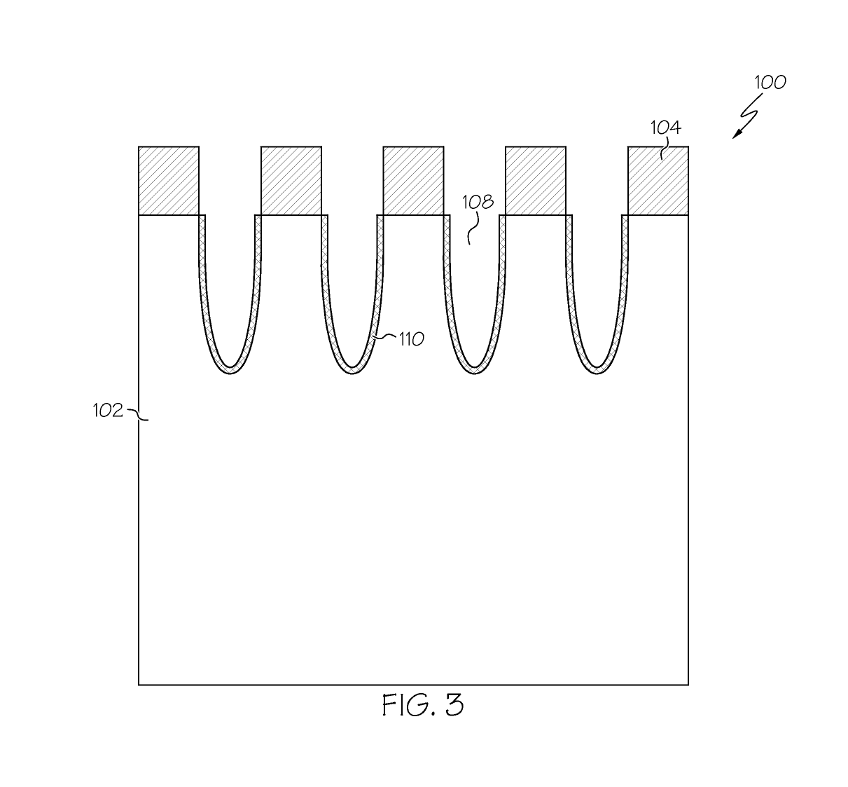

FIG. 3 shows semiconductor structure 100 after a subsequent process step of forming a surface treatment layer 110 on the interior surface of the cavities 108. The surface treatment layer 110 may comprise a nitride layer. The surface treatment layer 110 may comprise a silicon nitride layer. In some embodiments, surface treatment layer 110 has a thickness ranging from about 1 nanometer to about 2 nanometers. In other embodiments, surface treatment layer 110 has a thickness ranging from about 5 angstroms to about 15 angstroms. In some embodiments, the surface treatment layer 110 may be deposited via plasma-enhanced chemical vapor deposition (PECVD). In other embodiments, atomic layer deposition (ALD) may be used to deposit surface treatment layer 110. In other embodiments, an ion implantation process using nitrogen ions may be used to form the surface treatment layer 110. In yet other embodiments, the cavity 108 is subjected to a nitrogen-rich (N2) plasma to convert the interior surface of the cavity to nitride, rather than growing a physical nitride film. The surface treatment layer 110 preferably is hydrophobic, which reduces the undesirable fin sticking that can sometimes occur during post-etch wet cleaning processes. The surface treatment layer 110 also provides a benefit of protecting the upper portion of the cavity from being expanded during etch of a high aspect ratio cavity. This phenomenon, known as “necking” occurs due to reflected ions during a reactive ion etch process and can add variability to fin devices such as finFETs, fin diodes, fin resistors, and the like. This variability can adversely affect product yield, and hence, is undesirable.

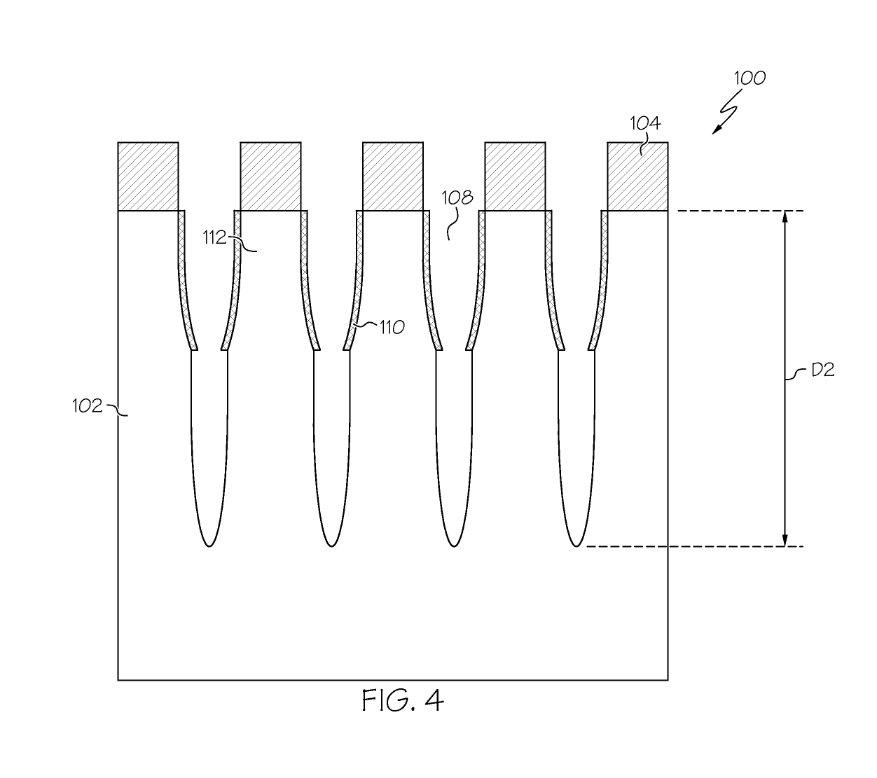

FIG. 4 shows semiconductor structure 100 after a subsequent process step of performing a second etch to extend the cavities 108 to a second depth of D2. In some embodiments, depth D2 may be in the range of about 180 nanometers to about 220 nanometers. In other embodiments, depth D2 may be in the range of about 230 nanometers to about 250 nanometers. The etch process for the second etch is an anisotropic etch, and may be a reactive ion etch. The etch removes the lower portion of the surface treatment layer 110. However, surface treatment layer 110 remains on the interior surface of the upper portion of the cavities 108 as shown in FIG. 4. In some embodiments, a separate etch process may be used to remove the lower portion of the surface treatment layer, followed by a reactive ion etch to extend the cavities to depth D2. Because the surface treatment layer 110 remains on the upper portion of the cavities, as defined by the first etch D1 (see FIG. 2), the upper portion of the cavities 108 are protected from reflected ions during the second etch, and hence, the shape of the fins 112 that are formed are of a consistent shape. In some embodiments, the formation of fins 112 is complete at this stage. From this point forward, standard fabrication techniques, such as deposition of gate dielectric films, gate materials, removal of any remaining surface treatment layer, removal of the pad nitride, and fin merging may take place to complete fabrication of the semiconductor device.

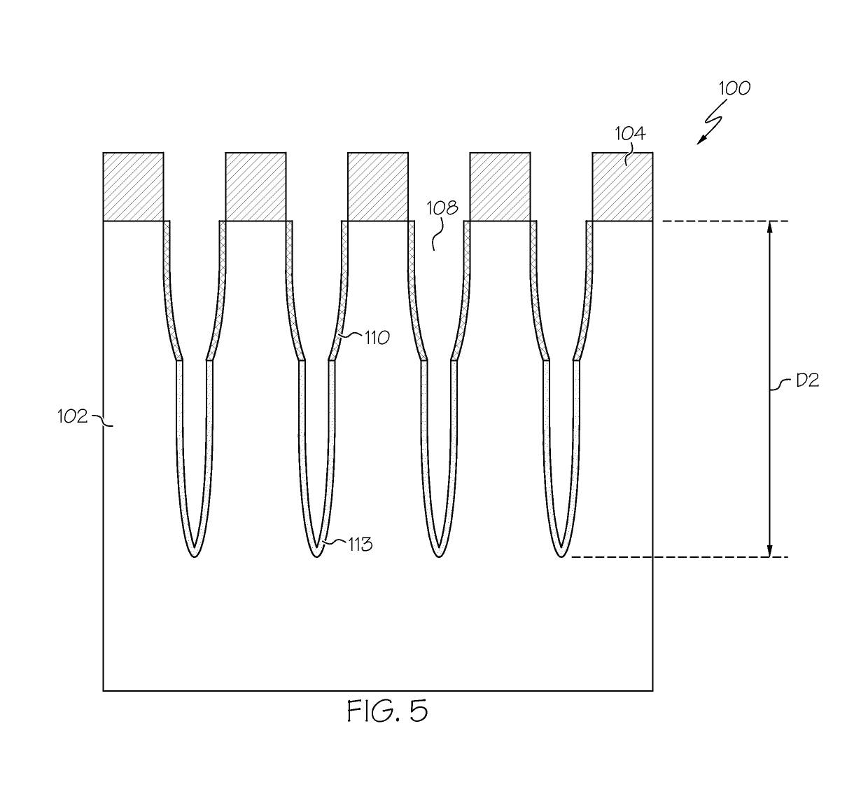

In some embodiments, the cycle of etching and then depositing a surface treatment layer may be repeated multiple times to form deeper fins. FIG. 5 shows semiconductor structure 100 after a step of depositing an additional surface treatment layer 113. Surface treatment layer 113 may be of a similar material, and be formed in a manner similar to that of surface treatment layer 110.

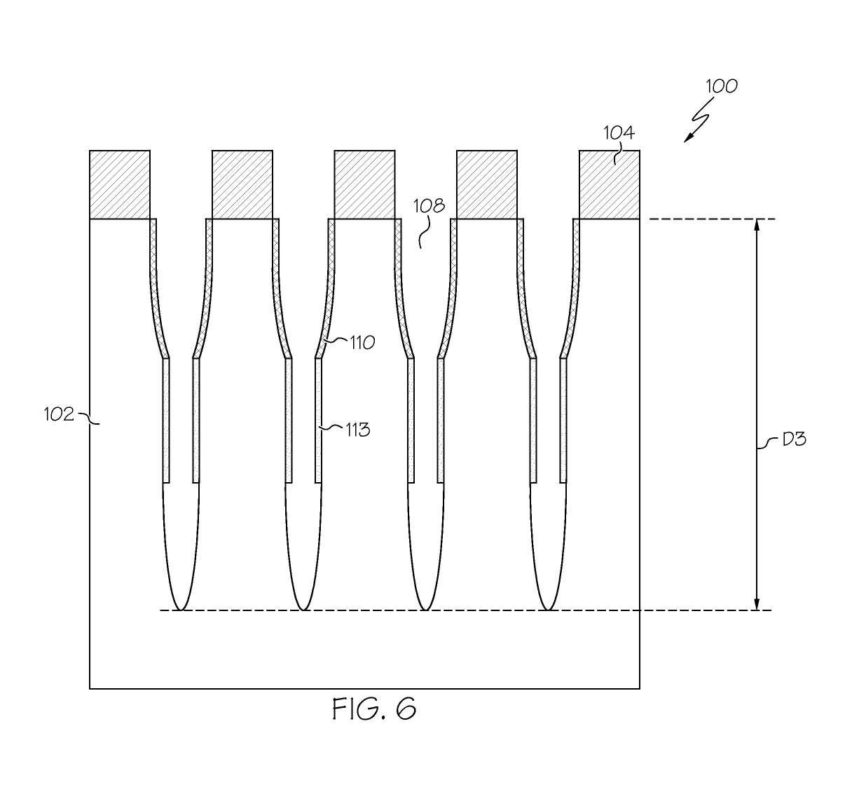

FIG. 6 shows semiconductor structure 100 after a subsequent step of performing a third etch to extend the cavities 108 to a third depth of D3. In some embodiments, depth D3 may be in the range of about 250 nanometers to about 290 nanometers. Using this method, deeper fins may be formed while the surface treatment layers 110 and 113 protect the fins from damage, or from sticking to each other during a subsequent post-etch wet clean process.

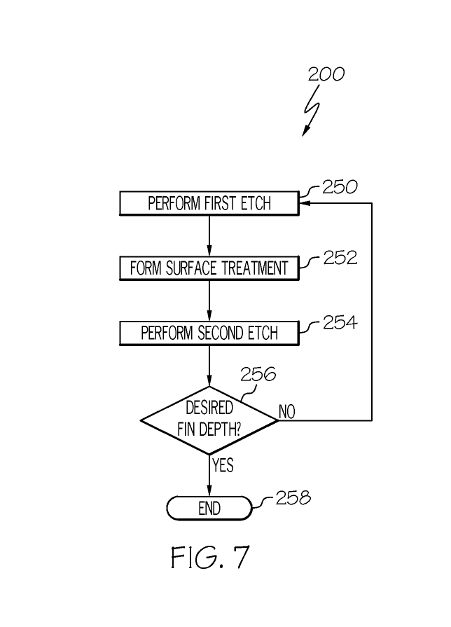

FIG. 7 is a flowchart 200 indicating process steps for embodiments of the present invention. In process step 250, a first etch is performed (see D1 of FIG. 2). In process step 252, a surface treatment is applied to the interior surface of the cavities (see 110 of FIG. 3). In process step 254, a second etch is performed (see D2 of FIG. 4). In process step 256, a check is made to see if the fins are of the desired height/depths. If the fins are of the desired height/depth, the process terminates in process step 258. If the fins are not yet at the desired depth, process steps 250, 252, and 254 may be repeated one or more times to achieve the desired fin depth.

In various embodiments, design tools can be provided and configured to create the datasets used to pattern the semiconductor layers as described herein. For example, data sets can be created to generate photomasks used during lithography operations to pattern the layers for structures as described herein. Such design tools can include a collection of one or more modules and can also include hardware, software, or a combination thereof. Thus, for example, a tool can be a collection of one or more software modules, hardware modules, software/hardware modules, or any combination or permutation thereof. As another example, a tool can be a computing device or other appliance on which software runs or in which hardware is implemented. As used herein, a module might be implemented utilizing any form of hardware, software, or a combination thereof. For example, one or more processors, controllers, application-specific integrated circuits (ASIC), programmable logic arrays (PLA)s, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

What is claimed is:

1. A method of forming fins in a semiconductor substrate, comprising:
forming a cavity in the semiconductor substrate, the cavity having a first depth;
forming a surface treatment on an interior surface of the cavity; and
extending the cavity to a second depth.

2. The method of claim 1, wherein forming a cavity having a first depth comprises forming a cavity having a depth ranging from about 20 nanometers to about 40 nanometers.

3. The method of claim 1, wherein forming a cavity having a first depth comprises forming a cavity having a depth ranging from about 30 nanometers to about 50 nanometers.

4. The method of claim 1, wherein forming a cavity is performed via an anisotropic etch process.

5. The method of claim 4, wherein the anisotropic etch process is a reactive ion etch process.

6. The method of claim 1, wherein forming a surface treatment on an interior surface of the cavity comprises subjecting the cavity to nitrogen plasma.

7. The method of claim 1, wherein forming a surface treatment on an interior surface of the cavity comprises performing a plasma-enhanced chemical vapor deposition process.

8. The method of claim 1, wherein forming a surface treatment on an interior surface of the cavity comprises performing an atomic layer deposition process.

9. The method of claim 6, wherein depositing a nitride layer comprises depositing a nitride layer having a thickness ranging from about 1 nanometer to about 2 nanometers.

10. The method of claim 6, wherein depositing a nitride layer comprises depositing a nitride layer having a thickness ranging from about 5 angstroms to about 15 angstroms.

11. The method of claim 1, wherein extending the cavity to a second depth comprises extending the cavity to a depth ranging from about 180 nanometers to about 220 nanometers.

12. The method of claim 1, wherein extending the cavity to a second depth comprises extending the cavity to a depth ranging from about 230 nanometers to about 250 nanometers.

13. The method of claim 1, wherein extending the cavity to a second depth comprises performing a reactive ion etch.

14. The method of claim 1, wherein forming a surface treatment on an interior surface of the cavity comprises performing an ion implantation process with nitrogen on the interior surface of the cavity.

15. A method of forming fins in a semiconductor substrate, comprising:
forming a plurality of cavities in the semiconductor substrate, the plurality of cavities each having a first depth;
forming a surface treatment on an interior surface of each cavity of the plurality of cavities;
extending each cavity of the plurality of cavities to a second depth; and
performing a wet clean process on the semiconductor substrate.

16. The method of claim 15, further comprising removing the surface treatment.

17. A method of forming fins in a semiconductor substrate, comprising:
forming a plurality of cavities in the semiconductor substrate, the plurality of cavities each having a first depth;
forming a first surface treatment on an interior surface of each cavity of the plurality of cavities;
extending each cavity of the plurality of cavities to a second depth;
forming a second surface treatment on the interior surface of each cavity of the plurality of cavities; and
extending each cavity of the plurality of cavities to a third depth.

18. The method of claim 17, wherein extending the cavity to a third depth comprises extending the cavity to a depth ranging from about 250 nanometers to about 290 nanometers.

19. The method of claim 18, wherein forming a first surface treatment and forming a second surface treatment comprise forming a nitride layer.

20. The method of claim 19, wherein the nitride layer has a thickness ranging from about 5 angstroms to about 15 angstroms.
